(19) United States
(12) Patent Application Publication
(10) Pub. No.: US 2025/0046654 A1
(43) Pub. Date: Feb. 6, 2025

(54) DIFFERENTIAL ETCH RATES OF COPPER FEATURES

(71) Applicant: INTERNATIONAL BUSINESS MACHINES CORPORATION, ARMONK, NY (US)

(72) Inventors: Mukta Ghate Farooq, HOPEWELL JUNCTION, NY (US); James J. Kelly, Schenectady, NY (US)

(21) Appl. No.: 18/363,775

(22) Filed: Aug. 2, 2023

(51) Int. Cl. H01L 21/768; H01L 23/00; H01L 23/532

(52) U.S. Cl. CPC H01L 21/76871; H01L 23/53238; H01L 24/05; H01L 2224/05155; H01L 2224/05644; H01L 2224/05647; H01L 2924/014

(57) ABSTRACT

Embodiments of present invention provide forming a seed layer on top of a supporting structure, the seed layer being a copper alloy with one or more alloying elements; forming a solder pad on top of and covering a portion of the seed layer; causing at least some of the one or more alloying elements to move into a lower region of the solder pad, thereby creating a first portion of the seed layer that is not covered by the solder pad and a second portion of the seed layer that is self-aligned to the solder pad, the second portion has a concentration level of the one or more alloying elements that is less than a concentration level of the one or more alloying elements of the first portion of the seed layer; and removing the first portion of the seed layer. A structure formed thereby is also provided.

### BACKGROUND

The present application relates to manufacturing of semiconductor integrated circuits. More particularly, it relates to method of creating differential etch rates for copper features and structure formed thereby.

A semiconductor chip includes various active and passive devices that are integrated on a semiconductor substrate. For example, the semiconductor chip may include front-end-of-line (FEOL) devices, middle-of-line (MOL) interconnects, and back-end-of-line (BEOL) structures and other power distribution networks (PDNs). With the recent advancement in semiconductor technology, some of the BEOL structures and PDNs are being moved to the backside of the semiconductor substrate for improved device efficiency, density, and reliability.

During the packaging process, the semiconductor chip may be connected to, for example, interposer through small copper micro bumps known as C4 (controlled collapse of chip connection) bumps. The C4 bumps may be manufactured by depositing a seed layer, creating a resist pattern on top of the seed layer, plating a copper layer on top of the seed layer in the resist pattern, plating a solder layer on top of the copper layer, and removing the resist pattern and portions of the seed layer that are not covered by the copper layer to form a solder pad, made of the copper layer, with the solder layer on top thereof. However, during the process of forming the solder pad, due to similarity in etch related material properties between the copper layer and the seed layer, undercut and/or damage becomes inevitable during a wet etch process in removing the portions of the seed layer.

### SUMMARY

Embodiments of present invention provide a semiconductor structure. The structure includes a seed layer, the seed layer being a copper alloy having one or more alloying elements to have a first concentration level of the one or more alloying elements; and a solder pad on top of and substantially aligned with the seed layer, where the solder pad has at least a first copper layer, the first copper layer includes a first region on top of a second region with the second region being directly on top of the seed layer, and the second region of the first copper layer has the one or more alloying elements to have a second concentration level of the one or more alloying elements. The one or more alloying elements in the second region of the first copper layer are diffused from the seed layer, which lowered a concentration level of the one or more alloying elements in the seed layer to the first concentration level.

In one embodiment, the second concentration level of the one or more alloying elements in the second region of the first copper layer is equal to or less than the first concentration level of the one or more alloying elements in the seed layer. This is achieved by the one or more alloying elements diffusing in a direction from the seed layer towards the second region of the first copper layer.

In another embodiment, the one or more alloying elements are more reactive to a wet etchant than copper to have a negative standard electromotive force potential, the wet etchant being a solution of at least water, hydrogen peroxide, and ammonium hydroxide or a solution of at least water, hydrogen peroxide, and phosphoric acid. For example, the one or more alloying elements may include Mn, Cr, Zn, Fe, and/or Co.

In one embodiment, the second concentration level of the one or more alloying elements increases in areas closer to the seed layer, in accordance with the direction of diffusion of the one or more alloying elements.

In another embodiment, the solder pad further includes a layer of nickel on top of the first copper layer, and a second copper layer on top of the layer of nickel, and wherein the solder pad has a horizontal width between about 5 μm and about 95 μm.

In yet another embodiment, sidewalls of the first and the second region of the first copper layer are surrounded by a protective liner, the protective liner being made of nickel, gold, or a combination of nickel and gold.

Embodiments of present invention provide a method of forming a semiconductor structure. The method includes forming a seed layer on top of a supporting structure, the seed layer being a copper alloy with one or more alloying elements; forming a solder pad on top of and covering a portion of the seed layer; causing at least some of the one or more alloying elements of the seed layer to move into a lower region of the solder pad, thereby creating a first portion of the seed layer that is not covered by the solder pad and a second portion of the seed layer that is self-aligned to the solder pad, the second portion of the seed layer has a concentration level of the one or more alloying elements that is less than a concentration level of the one or more alloying elements of the first portion of the seed layer; and removing the first portion of the seed layer. By having a higher concentration level, the first portion of the seed layer has a higher etch rate than the second portion of the seed layer that has a lower concentration level of the one or more alloying elements. In other words, a differential etch rate is created between the first and the second portion of the seed layer.

In one embodiment, removing the first portion of the seed layer includes etching the first portion of the seed layer selective to the second portion of the seed layer and selective to the solder pad. The selectivity is provided by the differential etch rate among the first portion, the second portion, and the solder pad.

In another embodiment, the solder pad includes at least a first copper layer, and removing the first portion of the seed layer includes etching the first portion of the seed layer by using an etchant in a wet etch process and in the presence of the first copper layer, the etchant being a solution containing at least water, hydrogen peroxide, and ammonium hydroxide or a solution containing at least water, hydrogen peroxide, and phosphoric acid.

In one embodiment, causing the at least some of the one or more alloying elements of the seed layer to move into the lower region of the solder pad includes subjecting the seed layer and the solder pad to an anneal process with an annealing temperature ranging from about 100 degree C. to about 400 degree C. and for a duration from about 30 seconds to about 90 minutes.

According to one embodiment, the one or more alloying elements are selected from a group consisting of Mn, Cr, Zn, Fe, and Co, the seed layer has a thickness ranging from about 50 nm to about 250 nm, and the solder pad has a horizontal width between about 5 μm and about 95 μm.

In one embodiment, the method further includes, before removing the first portion of the seed layer, selectively growing a protective liner on sidewalls of the solder pad, where the protective liner is made of nickel, gold, or a combination of nickel and gold.

### BRIEF DESCRIPTION OF THE DRAWINGS

The present invention will be understood and appreciated more fully from the following detailed description of embodiments of present invention, taken in conjunction with accompanying drawings of which:

FIGS. 1-3 are demonstrative illustrations of cross-sectional views of a semiconductor structure in several steps of manufacturing thereof according to embodiments of present invention; and

FIG. 4 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

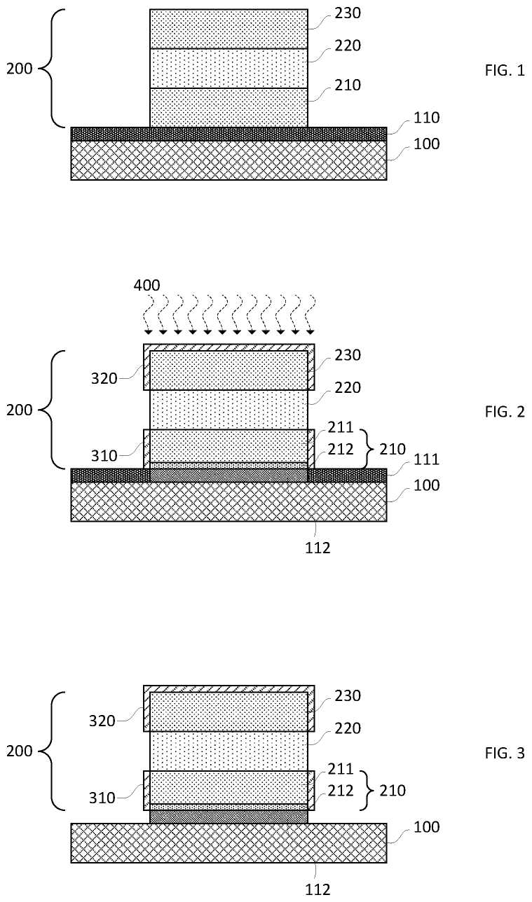

FIGS. 1-3 are demonstrative illustrations of cross-sectional views of a semiconductor structure in a step of manufacturing thereof according to one embodiment of present invention. More particularly, FIGS. 1-3 illustrate forming a solder pad during a C4 packaging process. However, embodiments of present invention are not limited in this aspect and may be generally applied to performing open etch, without protective mask, where undercuts are undesirable and should be avoided.

Particularly, embodiments of present invention provide receiving or providing a supporting structure 100 upon which a solder pad 200 is to be formed. The supporting structure 100 may include a semiconductor substrate with, for example, a layer of conductive material such as aluminum formed on top of a back-end-of-line (BEOL) structure in the substrate. In one embodiment, the supporting structure 100 may provide one or more conductive paths from the solder pad 200 to the underneath BEOL structure and, through the BEOL structure, to one or more front-end-of-line (FEOL) devices in the substrate. The solder pad 200 may include at least a first copper layer 210, which may be a layer of pure copper or may be substantially devoid of impurity. Optionally, the solder pad 200 may include a layer of nickel 220 on top of the first copper layer 210, and a second copper layer 230 on top of the layer of nickel 220. The solder pad 200 may have a width of at least 1 micrometer (μm), and in one embodiment may have a width between about 5 μm and about 95 μm.

Embodiments of present invention further provide forming a seed layer on top of the supporting structure 100. Generally, in forming a solder pad made of copper, a seed layer of pure copper is used. However, the use of pure copper creates difficulty in selectively removing the seed layer later after the solder pad is formed on top thereof. This is because the seed layer and the solder layer are both made of substantially the same copper material, with similarity in etch rate or etch selectivity, undercuts may occur at the edge of interface between the solder pad and the seed layer. In other words, when the portion of the seed layer not being covered by the solder pad is removed through a wet etch process, some of the portion of the seed layer covered by the solder pad may be removed as well, together with some portion of the solder pad next to the seed layer, causing damage to the solder pad such as weakening its attachment to the supporting structure 100.

In view of the above manufacturing difficulty, embodiments of present invention provide forming a seed layer 110 that is made of a copper alloy on top of the supporting structure 100. By applying selective alloying elements that are more reactive than copper to a wet etchant that is used later in removing the seed layer, the seed layer 110 may be made to have a higher etch rate than the first copper layer 210 of the solder pad 200. The wet etchant may be etch solutions that are, for example, mixtures of an oxidizing agent, such as hydrogen peroxide, and an acid, such as sulfuric and/or phosphoric acid. Other etch solutions such as alkaline solutions that complex the cupric ions, such as ammonium hydroxide, may be used as well. Alloying elements that are more reactive than copper may include those elements that have smaller or negative standard electromotive force potentials than copper. For example, while copper has a positive standard electromotive force potential of about +0.337 V vs. the standard hydrogen electrode (SHE), Mn, Cr, Zn, Fe, and Co all have negative standard electromotive force potentials and thus are more reactive than copper to the wet etchant. The seed layer 110 may be made to have a concentration level of the alloying elements from about 0.5 ATM % to about 20.0 ATM % such that it has an appreciable etch rate difference from that of the first copper layer 210. The wet etchant may be, as being described above, a solution including and/or containing at least water, hydrogen peroxide, and ammonium hydroxide, or a solution including and/or containing at least water, hydrogen peroxide, and phosphoric acid.

After forming the seed layer 110, which may be formed through a deposition process such as a physical vapor deposition (PVD) process, a chemical vapor deposition (CVD) process, or an atomic layer deposition (ALD) process to have a thickness ranging from about 50 nanometer (nm) to about 250 nm, embodiments of present invention provide forming the solder pad 200 on top of the seed layer 110. For example, a resist mask may first be formed and then patterned through a lithographic patterning process to have an opening on top of the seed layer 110. The solder pad 200 may then be formed through a plating process in the opening such as, for example, by plating the first copper layer 210, plating the layer of nickel 220, and plating the second copper layer 230. In one embodiment, a layer of solder material may be plated on top of the second copper layer 230 to form a solder bump (not shown). After the plating, the resist mask may be removed leaving only the solder pad 200 on top of the seed layer 110.

As is illustrated in FIG. 2, embodiments of present invention then provide, optionally, forming a protective liner 310 covering sidewalls of the first copper layer 210 and a protective liner 320 covering both sidewalls and top surface of the second copper layer 230. When a solder bump is formed on top of the second copper layer 230, the protective liner 320 may cover the top surface and sidewalls of the solder bump as well. The protective liners 310 and 320 may be nickel, gold, or a combination of nickel and gold in material and may be deposited selectively onto the surfaces of copper material of the first and the second copper layer 210 and 230. The protective liners 310 and 320 may help the first and the second copper layer 210 and 230 from being etched in a subsequent etching process that removes the portion of the seed layer 110 that is not covered by the solder pad 200.

Embodiments of present invention further provide causing at least some of the alloying elements in a portion of the seed layer 110 that is directly underneath the solder pad 200 to out-diffuse or move from the seed layer 110 into the above first copper layer 210. As a non-limiting example, embodiments of present invention provide subjecting the seed layer 110 and the solder pad 200 to an anneal process 400, in a temperature ranging from about 100 degree Celsius (C) to about 400 degree C., for a duration of ranging from about 30 seconds to 90 minutes. The anneal process 400 causes at least some of the alloying elements, which may be Mn, Cr, Zn, Fe, and/or Co, to move from the seed layer 110 to the first copper layer 210, resulting in a first portion 111 of the seed layer 110, which is not covered by the solder pad 200 and remains substantially the same as being deposited, and a second portion 112 of the seed layer 110. The second portion 112 of the seed layer 110 may be self-aligned to the solder pad 200 and is purified, to certain extent, to have a lowered concentration level of the alloying elements than that in the first portion 111 of the seed layer 110. For example, the alloying elements in the second portion 112 of the seed layer 110 may have a concentration level that is about 20 to 30% of the original concentration level. In one embodiment, the alloy elements in the second portion 112 of the seed layer 110 may have a concentration level ranging from about 0.1 ATM % to about 5.0 ATM %, while the alloy elements in the first portion 111 of the seed layer 110 may have a concentration level ranging from about 0.5 ATM % to about 20.0 ATM %.

The migration of the alloying elements into the first copper layer 210 may cause the creation of a first region 211 of the first copper layer 210 that remains substantially unaffected by the migration, and a second region 212 of the first copper layer 210 that is affected by the migration to have a concentration level of the alloying elements that is about 20 to 30% of the concentration level in the first portion 111 of the seed layer 110, and in one embodiment about 0.1 ATM % to about 5.0 ATM %. In other words, the concentration level of the alloying elements in the second region 212 of the first copper layer 210 may be equal to or less than the concentration level of the alloying elements in the second portion 112 of the seed layer 110. It is noted here that considering the nature of diffusion, the concentration level in the second region 212 may not be uniform and may increase or become higher in areas closer to the second portion 112 of the seed layer 110. In other words, the concentration level in the second region 212 may be non-uniform.

The lowering of concentration level of the alloying elements in the second portion 112 of the seed layer 110 may lower the etch rate of the second portion 112, creating a differential etch rate between the first portion 111 and the second portion 112 of the seed layer 110. The difference in etch rate enables the effective removal of the first portion 111 of the seed layer 110 in a later process without significantly or appreciably affecting the second portion 112 of the seed layer 110. In other words, an etching process of removing the first portion 111 of the seed layer 110 may significantly slow down once the first portion 111 is removed, resulting no impact, significantly less or no undercut in the second portion 112 at the edge of interface with the solder pad 200.

In the meantime, the second region 212 of the first copper layer 210 may have a concentration level of the alloying elements that is less than that of the second portion 112 of the seed layer 110, resulting no etching or at least no appreciable etching of the first copper layer 210 even when the first copper layer 210 is not protected by the optional protective liner 310.

As being illustrated in FIG. 3, after causing at least some of the alloying elements to out-diffuse or move into the first copper layer 210, embodiments of present invention provide selectively removing the first portion 111 of the seed layer 110 in a wet etch process and in the presence of the first copper layer 210. The wet etch process may employ an etchant that is specifically designed and/or formulated to be selective to the type of alloying elements used in forming the copper alloy of the seed layer 110. The removal of the first portion 111 of the seed layer 110 creates a solder pad 200 that has no appreciable undercut around edge of interface with the underneath second portion 112 of the seed layer 110, neither any appreciable undercut in the second portion 112 of the seed layer 110.

After the removal of the first portion 111 of the seed layer 110, if being optionally used, the protective liners 310 and 320 may remain surrounding and covering sidewalls and the top surface of the solder pad 200 and/or the solder bump, if being formed on top of the solder pad 200. However, embodiments of present invention are not limited in this aspect and in one embodiment the protective liner 310 and/or 320 maybe selectively removed.

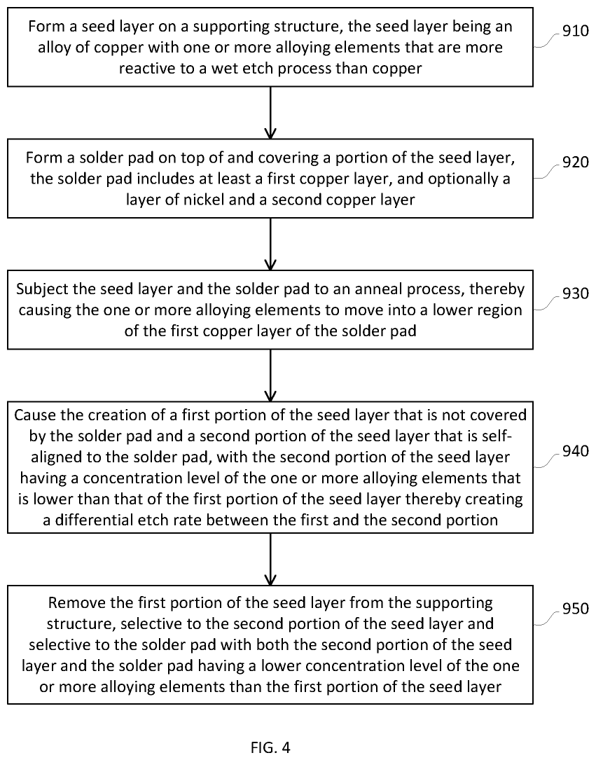

FIG. 4 is a demonstrative illustration of a flow-chart of a method of manufacturing a semiconductor structure according to embodiments of present invention. The method includes (910) forming a seed layer that is a copper alloy with one or more alloying elements that are more reactive to an etchant used in a wet etch process such as, in one embodiment, Mn, Cr, Zn, Fe, and/or Co; (920) forming a solder pad on top of and covering a portion of the seed layer, where the solder pad includes at least a first copper layer and optionally may include a layer of nickel on top of the first copper layer and a second copper layer on top of the layer of nickel; (930) subjecting the seed layer and the solder pad to an condition such as an anneal process that causes the one or more alloying elements to move into a lower region of the first copper layer of the solder pad; and with the condition such as the anneal process (940) causing the creation of a first portion of the seed layer that is not covered by the solder pad and a second portion of the seed layer that is self-aligned to the solder pad, with the second portion of the seed layer having a concentration level of the one or more alloying elements that is lower than the concentration level of the one or more alloying elements of the first portion of the seed layer, thereby creating a differential etch rate with a difference between that of the first portion and that of the second portion; (950) removing the first portion of the seed layer from the supporting structure selective to the second portion of the seed layer and selective to the solder pad, with both of which having a much lower concentration level of the one or more alloying elements than that of the first portion of the seed layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a seed layer, the seed layer being a copper alloy having one or more alloying elements; and
a solder pad on top of and substantially aligned with the seed layer,
wherein the solder pad has at least a first copper layer, the first copper layer includes a first region on top of a second region with the second region being directly on top of the seed layer, and the second region of the first copper layer has the one or more alloying elements.

2. The semiconductor structure of claim 1, wherein the one or more alloying elements in the seed layer has a first concentration level, and the one or more alloying elements in the second region of the first copper layer has a second concentration level, and the second concentration level is equal to or less than the first concentration level.

3. The semiconductor structure of claim 1, wherein the one or more alloying elements are more reactive to a wet etchant than copper to have a negative standard electromotive force potential, the wet etchant being a solution containing at least water, hydrogen peroxide, and ammonium hydroxide or a solution containing at least water, hydrogen peroxide, and phosphoric acid.

4. The semiconductor structure of claim 1, wherein the one or more alloying elements include Mn, Cr, Zn, Fe, and/or Co.

5. The semiconductor structure of claim 2, wherein the second concentration level of the one or more alloying elements in the second region of the first copper layer increases in areas closer to the seed layer.

6. The semiconductor structure of claim 1, wherein the solder pad further includes a layer of nickel on top of the first copper layer, and a second copper layer on top of the layer of nickel, and wherein the solder pad has a horizontal width between about 5 μm and about 95 μm.

7. The semiconductor structure of claim 1, wherein sidewalls of the first and the second region of the first copper layer are surrounded by a protective liner, the protective liner being made of nickel, gold, or a combination of nickel and gold.

8. A method of forming a semiconductor structure comprising:
forming a seed layer on top of a supporting structure, the seed layer being a copper alloy with one or more alloying elements;
forming a solder pad on top of and covering a portion of the seed layer;
causing at least some of the one or more alloying elements of the seed layer to move into a lower region of the solder pad, thereby creating a first portion of the seed layer that is not covered by the solder pad and a second portion of the seed layer that is self-aligned to the solder pad, the second portion of the seed layer has a concentration level of the one or more alloying elements that is less than a concentration level of the one or more alloying elements of the first portion of the seed layer; and
removing the first portion of the seed layer.

9. The method of claim 8, wherein removing the first portion of the seed layer comprises etching the first portion of the seed layer selective to the second portion of the seed layer and selective to the solder pad.

10. The method of claim 8, wherein the solder pad includes at least a first copper layer, and wherein removing the first portion of the seed layer comprises etching the first portion of the seed layer by using an etchant in a wet etch process and in the presence of the first copper layer, the etchant being a solution containing at least water, hydrogen peroxide, and ammonium hydroxide or a solution containing at least water, hydrogen peroxide, and phosphoric acid.

11. The method of claim 8, wherein causing the at least some of the one or more alloying elements of the seed layer to move into the lower region of the solder pad comprises subjecting the seed layer and the solder pad to an anneal process with an annealing temperature ranging from about 100 degree C. to about 400 degree C. and for a duration from about 30 seconds to about 90 minutes.

12. The method of claim 8, wherein the one or more alloying elements are selected from a group consisting of Mn, Cr, Zn, Fe, and Co, the seed layer has a thickness ranging from about 50 nm to about 250 nm, and the solder pad has a horizontal width between about 5 μm and about 95 μm.

13. The method of claim 8, further comprising, before removing the first portion of the seed layer, selectively growing a protective liner on sidewalls of the solder pad, wherein the protective liner is made of nickel, gold, or a combination of nickel and gold.

14. A method of forming a semiconductor structure comprising:
forming a seed layer on top of a supporting structure, the seed layer being a copper alloy with at least one alloying element;
forming a solder pad on top of and covering a portion of the seed layer;
causing at least some of the one alloying element of the seed layer to move into a lower region of the solder pad, thereby creating a first portion of the seed layer that is not covered by the solder pad and a second portion of the seed layer that is self-aligned to the solder pad, the second portion of the seed layer has a concentration level of the one alloying element that is less than a concentration level of the one alloying element of the first portion of the seed layer; and
removing the first portion of the seed layer.

15. The method of claim 14, wherein the solder pad includes a first copper layer, a layer of nickel on top of the first copper layer, and a second copper layer on top of the layer of nickel, further comprising selectively growing a protective liner on sidewalls of the first copper layer, wherein the protective liner is made of nickel, gold, or a combination of nickel and gold.

16. The method of claim 15, wherein removing the first portion of the seed layer comprises etching the first portion of the seed layer selective to the second portion of the seed layer and selective to the protective liner.

17. The method of claim 15, wherein removing the first portion of the seed layer comprises etching the first portion of the seed layer by using an etchant in a wet etch process and in the presence of the first copper layer, the etchant being a solution including at least water, hydrogen peroxide, and ammonium hydroxide or a solution including at least water, hydrogen peroxide, and phosphoric acid.

18. The method of claim 14, wherein causing some of the one alloying element of the seed layer to move into the lower region of the solder pad comprises subjecting the seed layer and the solder pad to an anneal process with an annealing temperature ranging from about 100 degree C. to about 400 degree C. and for a duration from about 30 seconds to about 90 minutes.

19. The method of claim 14, wherein the one alloying element is selected from a group consisting of Mn, Cr, Zn, Fe, and Co, the seed layer has a thickness ranging from about 50 nm to about 250 nm, and the solder pad has a horizontal width between about 5 μm and about 95 μm.

20. The method of claim 14, wherein the supporting structure is a semiconductor substrate with a back-end-of-line (BEOL) structure on top thereof, and wherein the seed layer is formed on top of the BEOL structure.
